(19) United States
(12) Patent Application Publication
(10) Pub. No.: US 2007/0035338 A1
(43) Pub. Date: Feb. 15, 2007

(54) Symmetric D flip-flop and phase frequency detector including the same

(75) Inventor: Woo-Young Jung, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/502,855

(22) Filed: Aug. 11, 2006

(30) Foreign Application Priority Data
Aug. 12, 2005 (KR) 10-2005-0074395

(51) Int. Cl. H03K 3/00

(52) U.S. Cl. 327/199; 327/12

(57) ABSTRACT

A symmetric D flip-flop and a phase frequency detector including the same are disclosed. The symmetric D flip-flop includes a first latch unit and a second latch unit. The first latch unit latches a data signal that is received from external source. The second latch unit receives the latched data from the first latch unit, and then outputs an output signal and an inverted output signal. In the second latch unit, a path for the output data and a path for the inverted output data have a symmetric architecture with each other. Since the symmetric D flip-flop has the symmetric architecture in which the elements of the same number are included on the path for the output signal and the path for the inverted output signal, phase difference between the output signal and the inverted output signal may be removed.

### CROSS-REFERENCE TO RELATED APPLICATION

This application claims priority under 35 USC § 119 to Korean Patent Application No. 10-2005-0074395, filed on Aug. 12, 2005, the contents of which are herein incorporated by reference in its entirety.

### BACKGROUND OF THE INVENTION

1. Field of the Invention

The present invention relate to a symmetric D flip-flop and a phase frequency detector including the same, more particularly to a symmetric D flip-flop and a phase frequency detector including the symmetric D flip-flop, in which an output signal and an inverted output signal are outputted through a symmetric path so that the phase difference between the two signals is reduced.

2. Description of the Related Art

In general, in digital data communication systems, a phase-locked loop (PLL) or a delay-locked loop (DLL) for signal synchronization is widely used to transmit reliable data at a high speed.

The PLL typically includes a phase frequency detector (PFD), a charge pump, a loop filter, a voltage controlled oscillator (VCO) and a divider.

The PFD detects a phase difference between a reference signal and a feedback signal from the VCO to output an up signal UP and a down signal DN. The up signal UP and the down signal DN are used as voltage control signals for controlling the VCO through the charge pump and the loop filter.

The PFD may be divided into a dynamic logic PFD and a complementary logic PFD. Since the dynamic logic PFD has a defect of being sensitive to skew about an input signal and large power consumption, a complementary logic PFD is more frequently utilized.

The complementary logic PFD detects a phase difference between a reference signal and a feedback signal to output an output signal to a charge pump in the shape of differential signal. That is, the complementary logic PFD outputs an up signal UP (or an inverted up signal UPB) and a down signal DN (or an inverted down signal DNB). A differential charge pump capable of interfacing differential signals is required to use the complementary logic PFD.

However, a conventional complementary logic PFD inevitably has a propagation delay due to architecture of a built-in D flip-flop.

FIG. 1 is a circuit diagram illustrating a D flip-flop utilized in a conventional PFD.

Referring to FIG. 1, the conventional D flip-flop 10 includes a master unit that latches an externally applied data, i.e., a first latch unit 20, and a slave unit that receives the data from the first latch unit 20 and stores the data, i.e., a second latch unit 30.

A first switching element 40, which is controlled by an inverted clock signal CLKB, is also disposed between the data input terminal and the first latch unit 20. A second switching element 50, which is controlled by a clock signal CLK, is disposed between the first latch unit 20 and the second latch unit 30.

The first switching element 40 and the second switching element 50 may be implemented with transmission gates of an inverter-type. For example, when the inverted clock signal CLKB, which is a control signal, transits to a high level, the first switching element 40 is activated and inverts the input data to output the inverted input data D to the first latch 20. On the contrary, when the inverted clock signal transits to a low level, the first switching element 40 is deactivated to intercept the data transmission. A transmission gate of this inverter-type is disclosed in Korean Patent Laid-Open Publication No. 2002-47251.

In turn, the first latch unit 20 includes a NOR gate 21 for receiving an output of the first switching element 40 and an inverted reset signal RNB, and a third switching element 22 which is controlled by a clock signal CLK and inversely coupled to the NOR gate 21 in parallel.

In addition, the second latch unit 30 includes a NAND gate 31 for receiving an output of the second switching element 50 and a reset signal RN, and a fourth switching element 32 which is controlled by an inverted clock signal CLKB and inversely coupled in parallel to the NAND gate 31.

In this case, a first inverter 60 for outputting an output signal Q is disposed connected to an output terminal of the NAND gate 31 and an input terminal of the fourth switching element 32. Second and third inverters 70 and 80 output an inverted output signal QB, and are coupled in series with each other.

When the clock signal CLK transits to a low level and the reset signal RN transits to a high level, the first and fourth switching elements 40 and 32 are activated and the second and third switching elements 50 and 22 are deactivated. Therefore, the input data D is transferred from the data input terminal to the master unit but the data transmission from the master unit to the slave unit is interrupted. Thus, the first and second latch units 20 and 30 are in a hold state, in which the previous state data is maintained.

When the clock signal CLK transits to a high level, the second and third switching elements 50 and 22 are activated and the first and fourth switching elements 40 and 32 are deactivated. Thus the previous state data may be transferred to the second latch unit 30.

On the other hand, when the reset signal RN for clearing the data transits to a low level, the low level signal is applied to the NAND gate 31 of the second latch unit 30, so the output of the NAND gate 31 has a high level regardless of an output signal of the third switching elements 50. Thus, an output signal Q, which corresponds to a signal inverted through the first inverter 60, is reset to ‘0’. On the contrary, an inverted output signal QB through the second and third inverters 70 and 80 is reset to ‘1’.

FIG. 2 is a schematic diagram illustrating the drawbacks of the conventional D flip-flop illustrated in FIG. 1.

Referring to FIG. 2, the conventional D flip-flop 10 includes only the first inverter 60 in the output terminal for outputting an output signal Q from the second latch unit, while including the second and third inverters 70 and 80 in the inverted output terminal for outputting an inverted output signal QB. That is, one more inverter is included in the inverted output terminal.

Thus, there is a path difference by one inverter delay time illustrated in FIG. 2 between a set operation path and a reset operation path for carrying out the set operation and the reset operation described above. Therefore, the output signal Q always leads the inverted output signal QB in set and reset operations.

The above-described phenomenon causes a time difference between UP and UPB signals or between the DN and DNB signals in the PFD, which outputs UP and UPB signals or DN and DNB signals to a differential charge pump. This time difference is a major source of a current mismatch in the differential charge pump.

### SUMMARY OF THE INVENTION

Accordingly, example embodiments of the present invention are provided to substantially obviate one or more problems due to limitations and disadvantages of the related art.

Some example embodiments of the present invention provide a symmetric D flip-flop, in which an output signal and an inverted output signal are outputted through a symmetric path so that the phase difference between two signals is reduced.

Other example embodiments of the present invention provide a phase frequency detector (PFD) having the symmetric D flip-flop to accurately output an up signal UP and an inverted up signal UPB, and/or a down signal DN and an inverted down signal DNB to a differential charge pump.

According to a first aspect, the present invention is directed to a symmetric D flip-flop that includes a first latch unit and a second latch unit. The first latch unit latches a data signal received from an external source. The second latch unit receives the latched data signal from the first latch unit to output an output signal and an inverted output signal. A path for the output signal and a path for the inverted output signal have a symmetric architecture with respect to each other.

The symmetric D flip-flop may further include a first switching element and a second switching element. The first switching element is coupled between a data input terminal for receiving the data signal and the first latch unit, and is controlled by an inverted clock signal received from external source. The second switching element is coupled between the first latch unit and the second latch unit, and is controlled by a clock signal received from external source.

The first switching element may invert the received data signal to transmit the inverted data signal to the first latch unit when the inverted clock signal corresponds to a high level, and may interrupt the transmission of the data signal when the inverted clock signal corresponds to a low level. In addition, the second switching element may invert the data signal that is latched in the first latch unit to transmit the data signal to the second latch unit when the clock signal corresponds to a high level, and may interrupt the transmission of the data signal when the clock signal corresponds to a low level.

The first latch unit may include a first NOR gate that receives an output of the first switching element and an inverted reset signal, and a third switching element that is controlled by the clock signal and inversely coupled in parallel to the first NOR gate.

The second latch unit may include a first inverter coupled to an output terminal of the second switching element; a NAND gate configured to receive an output of the first inverter and a reset signal; a second inverter configured to invert an output of the NAND gate to output the inverted output of the NAND gate as the output signal; a transmission gate coupled to an output terminal of the second switching element, and configured to be controlled by a power supply voltage; a second NOR gate configured to receive an output of the transmission gate and the inverted reset signal; a third inverter configured to invert an output of the NOR gate to output the inverted output of the NOR gate as the inverted output signal; and a fourth switching element inversely coupled between the second switching element and an output terminal of the second NOR gate, and configured to be controlled by the inverted clock signal.

In a set operation, the second latch unit outputs the output signal via the first inverter, the NAND gate and the second inverter, and outputs the inverted output signal via the transmission gate, the second NOR gate and the third inverter. In a reset operation the second latch unit outputs the output signal via the NAND gate and the second inverter, and outputs the inverted output signal via the second NOR gate and the third inverter.

According to another aspect, the present invention is directed to a phase frequency detector (PFD) including a first D flip-flop, a second D flip-flop, an AND gate and a delay unit. The first D flip-flop receives a reference signal through a first clock input terminal to output an up signal and an inverted up signal, in which the up signal transitions to high level when a rising edge of the reference signal is detected. In the first D flip-flop, the inverted up signal is outputted through a second path that is symmetric with a first path through which the up signal is outputted so that the up signal and the inverted up signal simultaneously transition. The second D flip-flop receives a feedback signal via a second clock input terminal to output a down signal and an inverted down signal, in which the down signal transitions to high level when a rising edge of the feedback signal is detected. In the second D flip-flop, the inverted down signal is outputted through a fourth path that is symmetric with a third path through which the down signal is outputted so that the down signal and the inverted down signal simultaneously transition. The AND gate executes an AND operation on the up and down signals output from the first and second D flip-flops. The delay unit delays an output of the AND gate by a predetermined time, and provides the delayed output of the AND gate to reset terminals of the first and second D flip-flops.

The first D flip-flop may include a first latch unit and a second latch unit. The first latch unit latches a data signal received from external source. The second latch unit receives the latched data signal from the first latch unit, and provides the up signal UP and the inverted up signal UPB. The second latch unit has the symmetric first and second paths through which the up signal and the inverted up signal are outputted, respectively.

The first D flip-flop may further include a first switching element coupled between a data input terminal and the first latch unit, and configured to be controlled by an inverted reference signal that is an inverted signal of the reference signal; and a second switching element coupled between the first latch unit and the second latch unit, and configured to be controlled by the reference signal.

The first switching element inverts the received data signal to transmit the data signal to the first latch unit when the inverted reference signal corresponds to high level, and interrupts the transmission of the data signal when the inverted reference signal corresponds to low level. In addition, the second switching element inverts a latched data signal in the first latch unit to transmit the data signal to the second latch unit when the inverted reference signal corresponds to high level, and interrupts the transmission of the data signal when the inverted reference signal corresponds to low signal.

The first latch unit may include a first NOR gate configured to receive an output of the first switching element and an inverted reset signal; and a third switching element inversely coupled in parallel to the first NOR gate, and configured to be controlled by the reference signal.

The second latch unit may include a first inverter coupled to an output terminal of the second switching element; a NAND gate configured to receive an output of the first inverter and a reset signal; a second inverter configured to invert an output of the NAND gate to output the inverted output of the NAND gate as the up signal; a transmission gate coupled to an output terminal of the second switching element, and configured to be controlled by a power supply voltage; a second NOR gate configured to receive an output of the transmission gate and the inverted reset signal; a third inverter configured to invert an output of the NOR gate to output the inverted output of the NOR gate as the inverted up signal; and a fourth switching element inversely coupled between the second switching element and an output terminal of the second NOR gate, and configured to be controlled by the inverted reference signal.

In a set operation, the second latch unit may output the up signal through the first inverter, the NAND gate and the second inverter, and may output the inverted up signal via the transmission gate, the second NOR gate and the third inverter. In a reset operation, the second latch unit may output the up signal through the NAND gate and the second inverter, and may output the inverted up signal via the second NOR gate and the third inverter.

The second D flip-flop may output the down signal and the inverted down signal through the symmetric third and fourth paths of the same symmetric architecture as the first D flip-flop. In the second D flip-flop, the down signal is input in place of the up signal and the feedback signal is input in place of the reference signal.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a circuit diagram illustrating a D flip-flop used in a conventional PFD.

FIG. 2 is a schematic diagram illustrating drawbacks of the conventional D flip-flop illustrated in FIG. 1.

FIG. 3 is a block diagram illustrating a PLL.

FIG. 4 is a graph illustrating a variance of the control voltage for controlling the VCO illustrated in FIG. 3.

FIG. 5 is a timing diagram illustrating states of major signals in REGION 1 illustrated in FIG. 4.

FIG. 6 is a timing diagram illustrating states of major signals in REGION 2 illustrated in FIG. 4.

FIG. 7 is a timing diagram illustrating states of major signals in REGION 3 illustrated in FIG. 4.

FIG. 8 is a circuit diagram illustrating a PFD including a symmetric D flip-flop according to an embodiment of the present invention.

FIG. 9 is a circuit diagram illustrating a first D flip-flop illustrated in FIG. 8.

FIG. 10 is a schematic diagram illustrating a set operation path and a reset operation path of a first D flip-flop illustrated in FIG. 9.

FIG. 11 is a graph illustrating output of a signal of the conventional D flip-flop illustrated in FIG. 1.

FIG. 12 is a graph illustrating output of a signal of a first D flip-flop illustrated in FIG. 10.

### DESCRIPTION OF THE PREFERRED EMBODIMENTS

Hereinafter, example embodiments of the present invention will be described in detail with reference to the accompanying drawings.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent”, etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

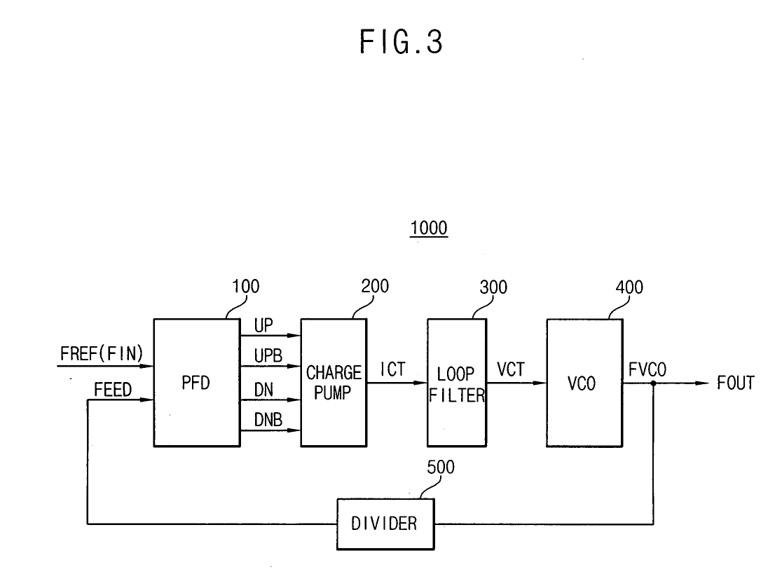

FIG. 3 is a block diagram illustrating a PLL according to an example embodiment of the present invention.

Referring to FIG. 3, a PLL 1000 includes a PFD 100, a charge pump 200, a loop filter 300, a VCO 400 and a divider 500.

The PFD 100 generates UP/UPB signals and DN/DNB signals that have information about a phase difference by comparing a reference signal FREF, i.e., an input signal, with a feedback signal FEED. The generated UP/UPB signals and DN/DNB signals are supplied to the charge pump 200, and a current signal ICT is generated in response to the phase difference.

The generated current signal ICT is converted to a voltage signal through the loop filter 300 and then provided as a control voltage VCT of the VCO 400. The VCO 400 generates a frequency-variable clock signal FVCO in response to a level of the control voltage VCT. The generated clock signal FVCO is divided at some division rate by the divider 500, and then provided to the PFD 100 as a feedback signal FEED again.

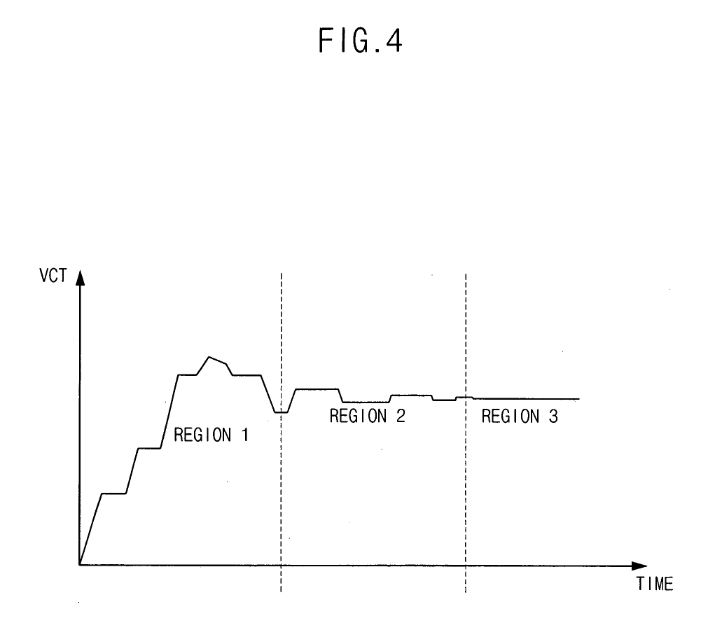

FIG. 4 is a graph illustrating a variation of the control voltage VCT for controlling the VCO 400.

Referring to FIG. 4, a variation of the control voltage VCT may be largely divided into three regions REGION1, REGION2 and REGION3. In REGION 1, the level of the control voltage VCT increases and decreases unstably and monotonously. In REGION 2, the level of the control voltage VCT alternatively increases and decreases and converges to a certain level. In addition, in REGION 3, i.e., in the lock region, the level of the control voltage becomes stabilized to the certain level.

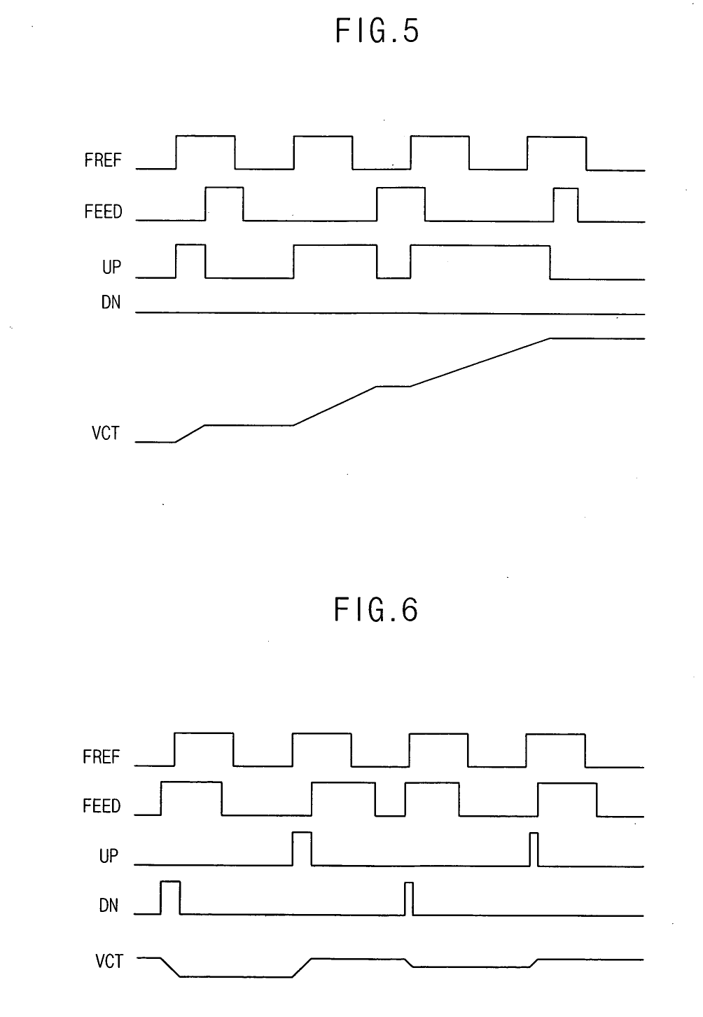

FIG. 5 is a timing diagram illustrating states of major signals in REGION 1 illustrated in FIG. 4.

Referring to FIG. 5, in REGION 1, there are frequency difference and skew difference between the reference signal FREF and the feedback signal FEED, and the pulse width of one of the UP and DN signals is relatively wide. As described above, the control voltage VCT is not uniform and increases monotonously. In this REGION 1, the PFD 100 operates as a frequency detector.

FIG. 6 is a timing diagram illustrating states of major signals in REGION 2 illustrated in FIG. 4.

Referring to FIG. 6, in REGION 2, a difference between the reference signal FREF and the feedback signal FEED is relatively small. The pulse widths of the UP and DOWN signals are rather narrow and the UP and DOWN signals remain in ‘0’ state for most of the time. As described above, in REGION 2, the level of the control voltage VCT alternatively increases and decreases and converges to a certain level. In this REGION 2, the PFD 100 operates as a phase detector.

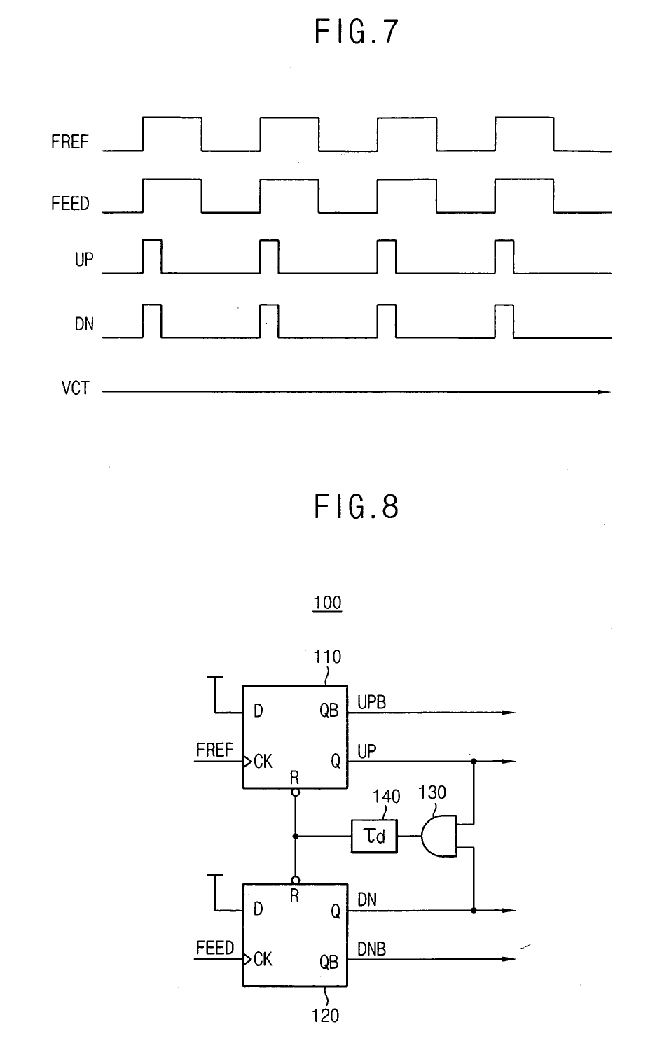

FIG. 7 is a timing diagram illustrating states of major signals in REGION 3 illustrated in FIG. 4.

Referring to FIG. 7, the feedback signal FEED is substantially the same as the reference signal FREF, and there is no phase skew between the two signals. Both the up signal UP and the down signal DN are constant and the control voltage VCT has a regular ripple. In REGION 3, the PFD 100 operates as a phase detector.

As described above, the PFD operates as a frequency detector in REGION 1, and operate as a phase detector in REGION 2 and REGION 3.

FIG. 8 is a circuit diagram illustrating a PFD including a symmetric D flip-flop according to an example embodiment of the present invention.

Referring to FIG. 8, the PFD 100 includes a first D flip-flop 110, a second D flip-flop 120, an AND gate 130 and a delay unit 140.

The first D flip-flop receives a reference signal FREF through a clock input terminal CK and outputs an up signal UP and a UPB signal that are rising to high levels when the rising edge of the reference signal is detected. The second D flip-flop 120 receives a feedback signal FEED through a clock input terminal CK and outputs a DN signal and a DNB signal that are rising to high levels when the rising edge of the feedback signal FEED is detected.

The AND gate 130 executes an AND operation of the up signal UP and the down signal DN that are outputted respectively from the first D flip-flop 110 and the second D flip-flop 120, and then provides the AND operated signal to the delay unit 140. The delay unit 140 delays the signal from the AND gate 130 for a predetermined time in order to clear the dead zone and applies the signal to reset terminals of the first and second D flip-flops. The signal is applied in an inverted type.

Accordingly, the PFD 100 outputs a high level signal when a rising edge of one of the reference signal FREF and the feedback signal FEED is first detected, that is, the faster signal. Additionally, when the slower signal triggers a high level signal, the AND gate 130 outputs a high level signal and the outputted signals are reset after the predetermined time is delayed to prevent a dead zone from being generated by the delay unit 140.

For example, when a rising edge of the reference signal FREF is first detected, an up signal UP with a high level is outputted. That is, the first D flip-flop executes a set operation. In this case, both the inverted up signal UPB and the down signal DN are output in low levels, and the inverted down signal DNB is output in high level.

When a rising edge of the feedback signal FEED is detected and the down signal DN transitions to a high level by the second D flip-flop 120 during the state described above, the output of the AND gate 130 transitions to a high level and the first D flip-flop and the second D flip-flop are reset to low levels. That is, the up signal UP and the inverted down signal DNB in high levels are reset to ‘0’.

However, the transmission times of the up and inverted up signals UP and UPB, and the down and inverted down signals DN and DNB must be the same for a smooth operation. Therefore, in example embodiments of the present invention, the first and the second flip-flops have the symmetric architecture so that the paths of the output signal Q and the inverted output signal QB are identical to each other.

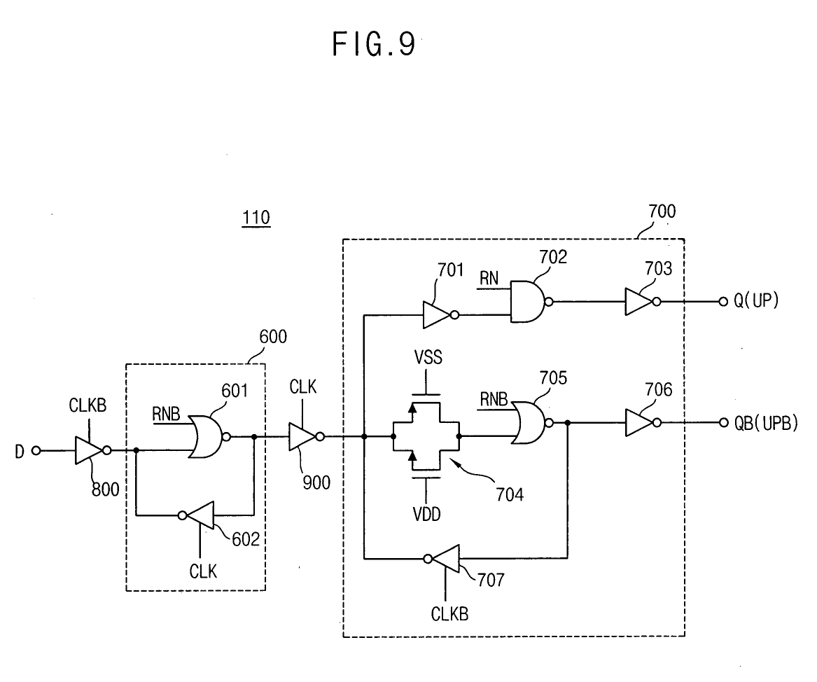

FIG. 9 is a circuit diagram illustrating a first D flip-flop illustrated in FIG. 8. The first D flip-flop 110 is illustrated in FIG. 9 to illustrate a symmetric D flip-flop according to the example embodiment of the present invention. The second D flip-flop also has the same symmetric architecture.

Referring to FIG. 9, a first D flip-flop 110 includes a first latch unit 600, i.e., a master unit, for latching an externally applied data signal D, a second latch unit 700, i.e., a slave unit, for receiving the latched data from the first latch unit 600, a first switching element 800 that is controlled by an inverted clock signal CLKB and disposed between a data input terminal and the first latch unit 600, and a second switching element 900 which is controlled by the clock signal CLK and disposed between the first latch unit 600 and the second latch unit 700. The first switching element 800 and the second switching element 900 may be implemented with transmission gates of an inverter-type.

The first latch unit 600 includes a first NOR gate 601 for receiving an output of the first switching element 800 and an inverted reset signal RNB, and a third switching element 602 which is controlled by the clock signal CLK and inversely coupled in parallel to the first NOR gate 601.

The second latch unit includes a first inverter 701 coupled to an output terminal of a second switching element 900, a NAND gate 702 for receiving an output of the first inverter 701 and a reset signal RN, a second inverter 703 for inverting an output of the NAND gate 702 and then outputting an output signal Q, a transmission gate 704 which is coupled to an output terminal of the second switching element 900 and controlled by a power supply voltage VDD, a second NOR gate 705 for receiving an output of the transmission gate 704 and the inverted reset signal RNB, a third inverter 706 for inverting an output of the NOR gate 705 and then outputting an inverted output signal QB, and a fourth switching element 707 which is controlled by the inverted clock signal CLKB and inversely coupled in parallel between the second switching element 900 and an output terminal of the second NOR gate 705.

Hereinafter, the operations of the D flip-flop 10 will be described.

When the clock signal CLK transits to a low level and a reset signal RN transits to a high level, the first and fourth switching elements 800 and 707 are activated and the second and third switching elements 900 and 602 are deactivated. That is, the input data signal D is transferred from the data input terminal to the master unit, but the transmission of the input data signal D from the master unit to the slave unit is interrupted. Thus, the first and second latch units 600 and 700 are in hold states, in which the previous state data is maintained.

When the clock signal CLK transits to a high level, the second and the third switching elements 900 and 602 are activated, and the first and the fourth switching elements 800 and 707 are deactivated. Therefore, the previous state data is transferred to the second latch unit 700.

On the other hand, when a reset signal RN for clearing data transits to a low level, the low level signal is input to the NAND gate 702 of the second latch unit 700, and then the output of the NAND gate 702 has a high level regardless of an output signal of the first inverter 701. Thus, the output signal Q, which corresponds to a signal inverted by the second inverter 703, is reset to ‘0’. On the contrary, when the inverted reset signal RNB of a high level signal is input to the second NOR gate 705, the output of the second NOR gate becomes a low level regardless of an output signal of the transmission gate 704. As a result, the inverted output QB, which corresponds to a signal inverted by a third inverter 706, is reset to ‘1’. The reset signal RN is an inverted signal of a signal received from the delay unit 140, thereby operating negatively.

In FIG. 9, the output signal Q corresponds to the up signal UP and the inverted output signal QB corresponds to the inverted up signal UPB. In addition, the clock signal CLK corresponds to the reference signal REF and the inverted clock signal CLKB corresponds to the inverted signal of the reference signal FREF.

In the case that the described D flip-flop of FIG. 9 corresponds to a second D flip-flop, the output signal Q corresponds to the down signal DN and the inverted output signal QB corresponds to the inverted down signal DNB. In addition, the clock signal CLK corresponds to the feedback signal FEED and the inverted clock signal corresponds to the reference signal FREF.

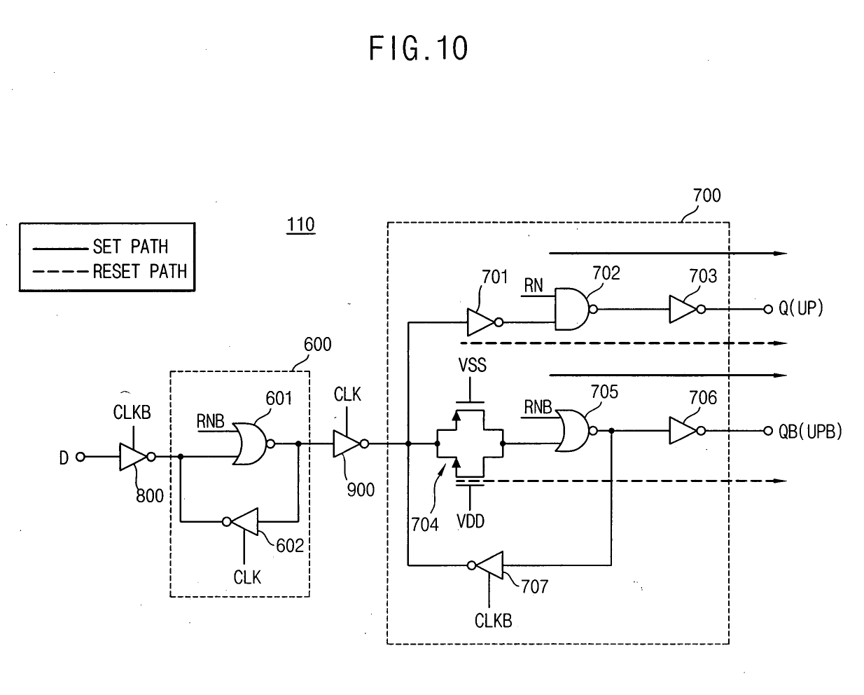

FIG. 10 is a schematic diagram illustrating a set operation path and a reset operation path of a first D flip-flop illustrated in FIG. 9.

Referring to FIG. 10, during a set operation that the output signal Q is outputted as ‘1’, the signal passes through a first inverter 701, a NAND gate 702, and a second inverter 703. Here, the inverted output signal QB has to be outputted as ‘0’, hence signal passes through a transmission gate 704, a second NOR gate 705 and a third inverter 706. Thus, the numbers of the elements through which the output signal Q and the inverted output signal QB respectively pass are the same in a set operation.

As described above, because output paths for the output signal Q and the inverted output signal QB are symmetric in a set operation, a phase difference between the output signal Q and the inverted output signal QB is prevented.

In a reset operation that the output signal Q corresponding to the reset signal RN is outputted as ‘0’, the signal passes through a NAND gate 702 and a second inverter 703. Here, the inverted output signal QB is outputted as ‘1’ so that the signal passes through a second NOR gate 705 and a third inverter 706. Thus, the numbers of the elements through which the output signal Q and the inverted output signal QB respectively pass are the same in a reset operation.

Because output paths for the output signal Q and the inverted output signal QB are symmetric during a reset operation, a phase difference between the output signal Q and the inverted output signal QB is prevented.

As a result, the current mismatch in the charge pump may be eliminated because the output signal Q, i.e., the up signal UP (the down signal DN in case of a second D flip-flop) and the inverted output signal QB, i.e., the inverted up signal UPB (the inverted down signal DNB in case of a second D flip-flop) are accurately transmitted without phase difference.

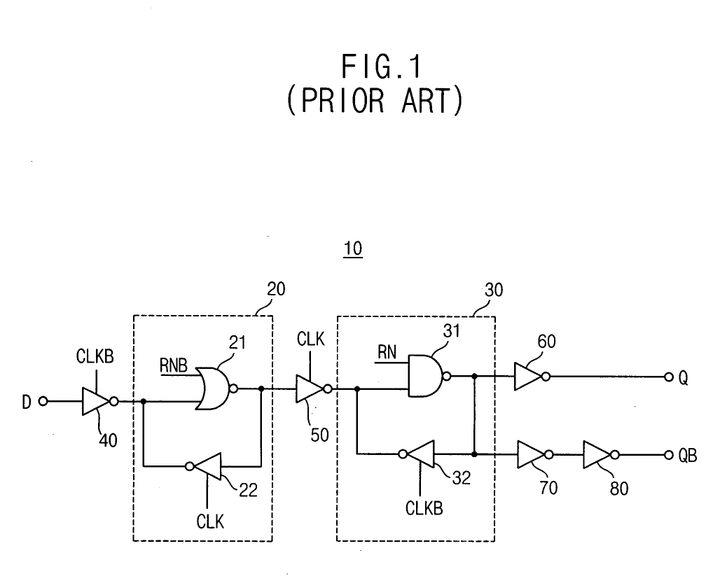

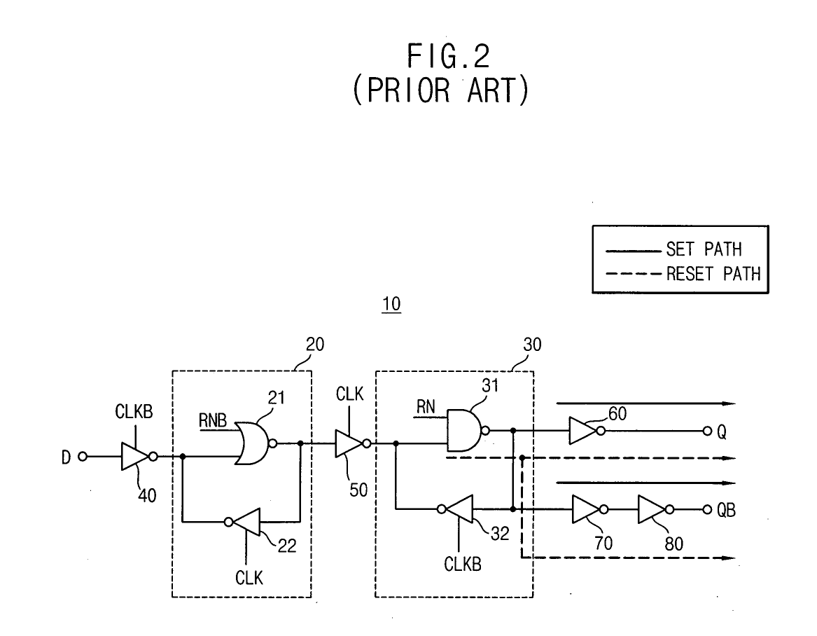

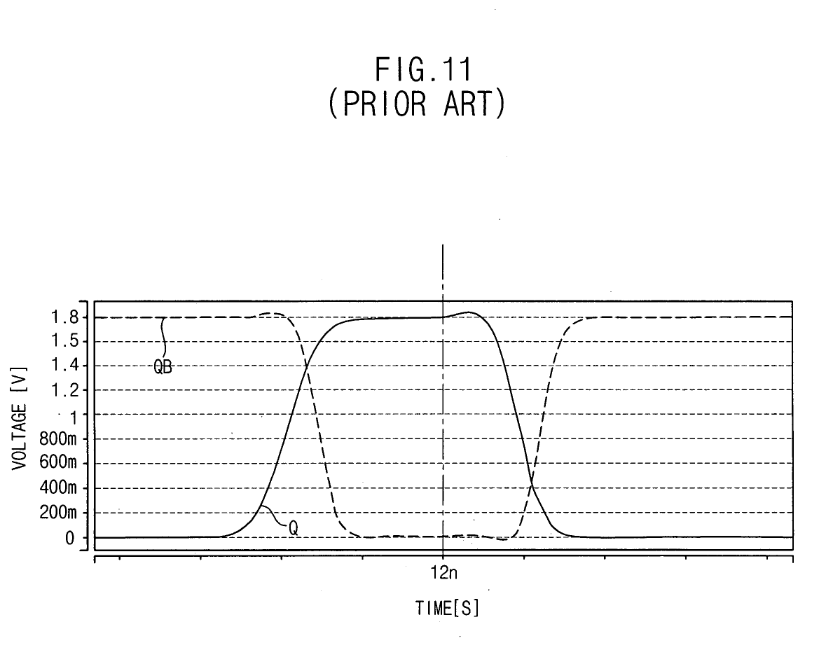

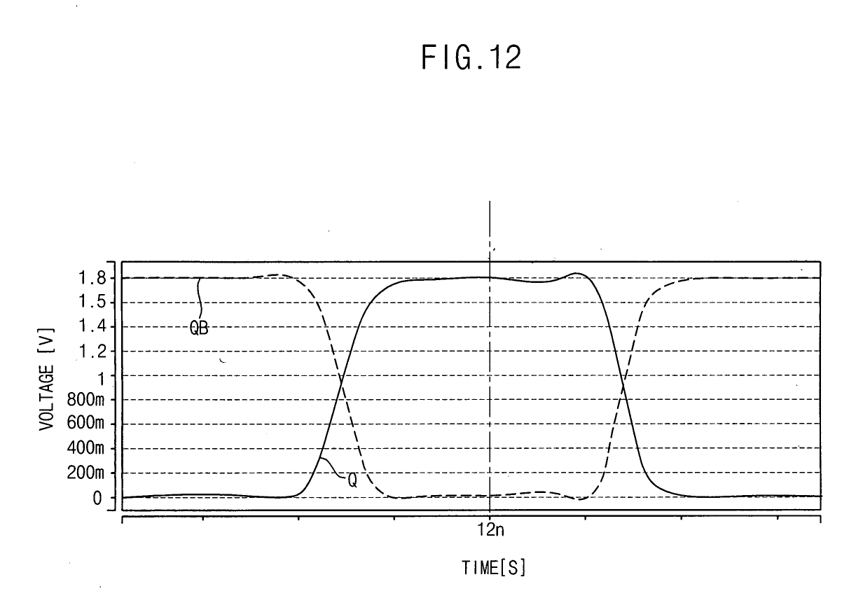

FIG. 11 is a graph illustrating output of a signal of the conventional D flip-flop 10 illustrated in FIG. 1, and FIG. 12 is a graph illustrating output of a signal of a first D flip-flop 110 illustrated in FIG. 10.

Considering an output signal Q and an inverted output signal QB of the conventional D flip-flop 10 in FIG. 11, the output signal Q leads the inverted output signal QB due to asymmetric architecture.

Referring to FIG. 12, accurate differential signals are generated in the D flip-flop according to the example embodiment of the present invention since phase difference between the output signal Q and the inverted output signal QB does not occur.

As described above, the symmetric D flip-flop according to the example embodiments of the present invention may reduce the phase difference between the output signal and the inverted output signal since the D flip-flop has the symmetric architecture in which the numbers of the elements through which the output signal and the inverted output signal respectively pass are the same.

Therefore, the phase frequency detector the symmetric D flip-flop according to the example embodiments of the present invention may output accurate output signals and may prevent a mismatch of the current from a charge pump, thereby removing a static phase error that is important in a phase synchronization loop.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A symmetric D flip-flop comprising:
a first latch unit configured to latch a data signal received from external source; and
a second latch unit configured to receive the latched data signal from the first latch unit to output an output signal and an inverted output signal, wherein a path for the output signal and a path for the inverted output signal have a symmetric architecture.

2. The symmetric D flip-flop of claim 1, further comprising:
a first switching element coupled between a data input terminal for receiving the data signal and the first latch unit, and configured to be controlled by an inverted clock signal received from external source; and
a second switching element coupled between the first latch unit and the second latch unit, and configured to be controlled by a clock signal received from external source.

3. The symmetric D flip-flop of claim 2, wherein the first switching element is configured to invert the received data signal to transmit the inverted data signal to the first latch unit when the inverted clock signal corresponds to a high level, and is configured to interrupt the transmission of the data signal when the inverted clock signal corresponds to a low level.

4. The symmetric D flip-flop of claim 2, wherein the second switching element is configured to invert the data signal that is latched in the first latch unit to transmit the data signal to the second latch unit when the clock signal corresponds to a high level, and is configured to interrupt the transmission of the data signal when the clock signal corresponds to a low level.

5. The symmetric D flip-flop of claim 2, wherein the first latch unit comprises:
a first NOR gate configured to receive an output of the first switching element and an inverted reset signal; and
a third switching element that is controlled by the clock signal and inversely coupled in parallel to the first NOR gate.

6. The symmetric D flip-flop of claim 2, wherein the second latch unit comprises:
a first inverter coupled to an output terminal of the second switching element;
a NAND gate configured to receive an output of the first inverter and a reset signal;
a second inverter configured to invert an output of the NAND gate to output the inverted output of the NAND gate as the output signal;
a transmission gate coupled to an output terminal of the second switching element, and configured to be controlled by a power supply voltage;
a second NOR gate configured to receive an output of the transmission gate and the inverted reset signal;
a third inverter configured to invert an output of the NOR gate to output the inverted output of the NOR gate as the inverted output signal; and
a fourth switching element inversely coupled between the second switching element and an output terminal of the second NOR gate, and configured to be controlled by the inverted clock signal.

7. The symmetric D flip-flop of claim 6, wherein the second latch unit outputs the output signal via the first inverter, the NAND gate and the second inverter, and outputs the inverted output signal via the transmission gate, the second NOR gate and the third inverter, in a set operation.

8. The symmetric D flip-flop of claim 6, wherein the second latch unit outputs the output signal via the NAND gate and the second inverter, and outputs the inverted output signal via the second NOR gate and the third inverter, in a reset operation.

9. A phase frequency detector comprising:
a first D flip-flop configured to receive a reference signal through a first clock input terminal to output an up signal and an inverted up signal, the up signal transitioning to high level when a rising edge of the reference signal is detected, the inverted up signal being outputted through a second path that is symmetric with a first path through which the up signal is outputted so that the up signal and the inverted up signal simultaneously transition;
a second D flip-flop configured to receive a feedback signal via a second clock input terminal to output a down signal and an inverted down signal, the down signal transitioning to high level when a rising edge of the feedback signal is detected, the inverted down signal being outputted through a fourth path that is symmetric with a third path through which the down signal is outputted so that the down signal and the inverted down signal simultaneously transition;
an AND gate configured to execute an AND operation on the up and down signals output from the first and second D flip-flops; and
a delay unit configured to delay an output of the AND gate by a predetermined time, and configured to provide the delayed output of the AND gate to reset terminals of the first and second D flip-flops.

10. The phase frequency detector of claim 9, wherein the first D flip-flop comprises:
a first latch unit configured to latch a data signal received from external source; and
a second latch unit configured to receive the latched data signal from the first latch unit, and provide the up signal UP and the inverted up signal UPB, the second latch unit having the symmetric first and second paths through which the up signal and the inverted up signal are outputted, respectively.

11. The phase frequency detector of claim 10, wherein the first D flip-flop further comprises:
a first switching element coupled between a data input terminal and the first latch unit, and configured to be controlled by an inverted reference signal that is an inverted signal of the reference signal; and
a second switching element coupled between the first latch unit and the second latch unit, and configured to be controlled by the reference signal.

12. The phase frequency detector of claim 11, wherein the first switching element is configured to invert the received data signal to transmit the data signal to the first latch unit when the inverted reference signal corresponds to high level, and is configured to interrupt the transmission of the data signal when the inverted reference signal corresponds to low level.

13. The phase frequency detector of claim 11, wherein the second switching element is configured to invert a latched data signal in the first latch unit to transmit the data signal to the second latch unit when the inverted reference signal corresponds to high level, and is configured to interrupt the transmission of the data signal when the inverted reference signal corresponds to low signal.

14. The phase frequency detector of claim 11, wherein the first latch unit comprises:
a first NOR gate configured to receive an output of the first switching element and an inverted reset signal; and
a third switching element inversely coupled in parallel to the first NOR gate, and configured to be controlled by the reference signal.

15. The phase frequency detector of claim 11, wherein the second latch unit comprises:
a first inverter coupled to an output terminal of the second switching element;
a NAND gate configured to receive an output of the first inverter and a reset signal;
a second inverter configured to invert an output of the NAND gate to output the inverted output of the NAND gate as the up signal;
a transmission gate coupled to an output terminal of the second switching element, and configured to be controlled by a power supply voltage;
a second NOR gate configured to receive an output of the transmission gate and the inverted reset signal;
a third inverter configured to invert an output of the NOR gate to output the inverted output of the NOR gate as the inverted up signal; and
a fourth switching element inversely coupled between the second switching element and an output terminal of the second NOR gate, and configured to be controlled by the inverted reference signal.

16. The phase frequency detector of claim 15, wherein the second latch unit outputs the up signal through the first inverter, the NAND gate and the second inverter, and outputs the inverted up signal via the transmission gate, the second NOR gate and the third inverter, in a set operation.

17. The phase frequency detector of claim 15, wherein the second latch unit outputs the up signal through the NAND gate and the second inverter, and outputs the inverted up signal via the second NOR gate and the third inverter, in a reset operation.

18. The phase frequency detector of claim 10, wherein the second D flip-flop outputs the down signal and the inverted down signal through the symmetric third and fourth paths of the same symmetric architecture as the first D flip-flop.
